(19) United States
(12) Patent Application Publication
(10) Pub. No.: US 2014/0002962 A1
(43) Pub. Date: Jan. 2, 2014

(54) ELECTRONIC DEVICE OPENING/CLOSING CONTROL MECHANISM

(71) Applicants: CHIEN CHENG MAI, NEW TAIPEI CITY (TW); HSIU FAN HO, NEW TAIPEI CITY (TW)

(72) Inventors: CHIEN CHENG MAI, NEW TAIPEI CITY (TW); HSIU FAN HO, NEW TAIPEI CITY (TW)

(73) Assignee: FIRST DOME CORPORATION, NEW TAIPEI CITY (TW)

(21) Appl. No.: 13/534,103

(22) Filed: Jun. 27, 2012

(51) Int. Cl. H05K 7/00

(52) U.S. Cl. 361/679.01

(57) ABSTRACT

An electronic device opening/closing control mechanism includes a connection arm movable between a first position and a second position. The connection arm has a first end and a second end. An elastic unit is disposed at the first end of the connection arm to normally apply an elastic force to the connection arm for keeping the connection arm positioned in the first position. A locking section is disposed at the second end of the connection arm. The locking section is held in a dent formed on the electronic device. When the connection arm is moved to the second position, the locking section is released from the held state, permitting the electronic device to be opened. The control mechanism overcomes the problem existing in the conventional locking device that under limitation of the space of the electronic device, the locking device cannot be easily mounted on the electronic device.

### BACKGROUND OF THE INVENTION

1. Field of the Invention

The present invention relates generally to an electronic device opening/closing control mechanism, and more particularly to an electronic device opening/closing control mechanism, which includes a connection arm movable between a first position and a second position for controlling locking/unlocking of the electronic device. The connection arm can be easily mounted on the electronic device without being limited by the space or volume of the electronic device.

2. Description of the Related Art

There are various electronic devices provided with covers or display screens, such as cellular phones, notebook computers, electronic books and digital imagers. The covers or display screens are pivotally mounted on the electronic devices via pivot pins (or rotational shafts), whereby the covers or display screens can be freely rotated and opened/closed under external force. For example, conventional skill discloses a sealed high-locating-force computer product rotational shaft structure. Another conventional skill discloses an elastic body assembly structure of hinge device. Another conventional skill further discloses a hinge device with multiple frictional interfaces. These Patents provide several typical embodiments of assembly of pivot pin and locating component (or locating module).

Basically, in the conventional locating module, multiple disc-shaped washers are stacked in the same direction or reverse direction and assembled on the pivot pin. The washers are tightened by a nut, whereby when the pivot pin is rotated, the washers provide an elastic holding effect or frictional resistance against the rotation of the cover or display screen so as to locate the cover or display screen in a desired position after opened.

In the above assembly of pivot pin and locating component for locating the cover or display screen of the electronic device after opened, the elastic holding effect or frictional resistance is adjustable by means of adjusting the tightness of the nut. Therefore, when a user rotates the cover or display screen around the axis of the rotational shaft (or pivot pin) to close the cover or display screen onto the device body module of the electronic device, the elastic force of the rotational shaft will make the cover or display screen slightly rebound or restore. That is, the rotational angle of the rotational shaft should be slightly larger than the closing angle of the cover or display screen so as to fully close the cover or display screen onto the device body module.

To solve the above problem, in practice, generally a locking unit is disposed on one side of the electronic device, which side is proximal to the user for forcedly locking the cover or display screen with the device body module in a fully closed state. However, there is a trend to design more lightweight, miniaturized and slimmed electronic device. Therefore, the interior space of the electronic device has become smaller and smaller. As a result, it often takes place that the proximal side of the electronic device can hardly provide sufficient space for mounting the locking unit therein. To overcome this problem, it is necessary to increase the total thickness or volume of the electronic device. This is not what we expect.

According to the aforesaid, it is known that the structural design of the cover or display screen, the device body module and the relevant components (such as the pivot pin, the locating module and the locking unit) of the conventional device has some shortcomings that need to be overcome. It is therefore tried by the applicant to provide an electronic device opening/closing control mechanism to eliminate the problems existing in the conventional device. Without changing the lightweight, miniaturized and slimmed structure of the electronic device or being limited by the interior space of the electronic device, the electronic device opening/closing control mechanism can be mounted on one side of the electronic device, which side is proximal to the user.

### SUMMARY OF THE INVENTION

It is therefore a primary object of the present invention to provide an electronic device opening/closing control mechanism. The control mechanism includes a connection arm movable between a first position and a second position. The connect ion arm has a first end and a second end. An elastic unit is disposed at the first end of the connection arm to normally apply an elastic force to the connection arm for keeping the connection arm positioned in the first position. A locking section is disposed at the second end of the connection arm. The locking section is held in a dent formed on the electronic device. When the connection arm is moved to the second position, the locking section is released from the held state, permitting the electronic device to be opened. The control mechanism overcomes the problem existing in the conventional locking device that under limitation of the space of the electronic device, the locking device cannot be easily mounted on the electronic device.

To achieve the above and other objects, the electronic device opening/closing control mechanism of the present invention is assembled with an electronic device. The electronic device includes a movable module (such as a cover or a display screen) and a device body module. The connection arm is disposed on the movable module. The dent is formed on the device body module. The locking section has a latch and a guide section. The dent is formed with a stop section and a sidewall corresponding to the latch and the guide section respectively. When the connection arm is moved between the first and second positions, the guide section of the locking section is moved along the sidewall of the dent and the latch is latched with the stop section to lock the movable module in a fully closed state or unlatched from the stop section, permitting the movable module to be opened.

The connection arm is formed with at least one restriction section and at least one stop section is disposed on the movable module corresponding to the restriction section. The restriction section is assembled with the stop section of the movable module to together define a move range of the connection arm. The restriction section is in the form of a slot, while the stop section is in the form of a pile corresponding to the slot form of the restriction section.

The present invention can be best understood through the following description and accompanying drawings, wherein:

### BRIEF DESCRIPTION OF THE DRAWINGS

FIG. 1 is a perspective view of the present invention, showing that the connection arm is assembled with an electronic device;

FIG. 2 is a perspective exploded view according to FIG. 1, showing the arrangement relationship between the connection arm, the locking section and the dent;

FIG. 3 is a perspective view showing the connection arm of the present invention and the cavity of the movable module for receiving the connection arm;

FIG. 4 is a sectional view of the present invention, showing that the connection arm is positioned in the first position and the latch of the locking section is latched with the stop section in a locked state; and

FIG. 5 is a sectional view of the present invention, showing that the connection arm is positioned in the second position and the latch of the locking section is unlatched from the stop section in an unlocked state.

### DETAILED DESCRIPTION OF THE PREFERRED EMBODIMENTS

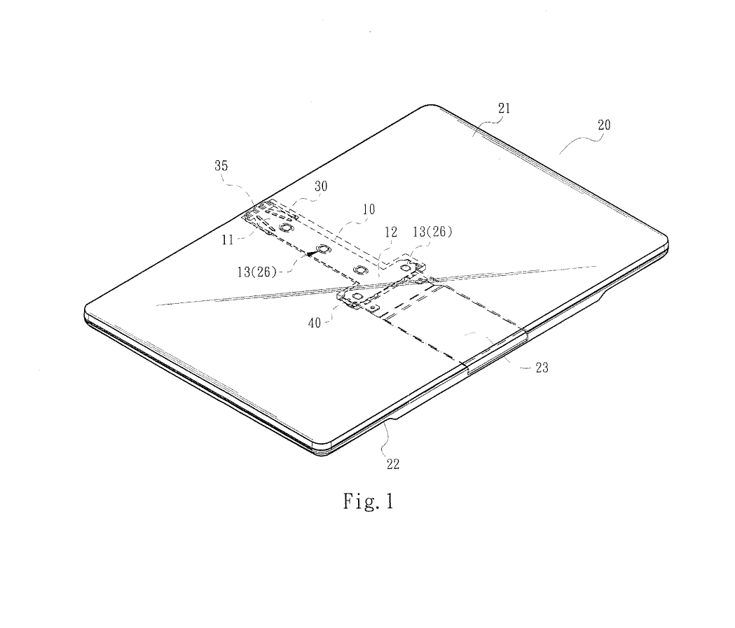

Please refer to FIGS. 1, 2 and 3. The electronic device opening/closing control mechanism of the present invention includes a connection arm 10 assembled with an electronic device 20. The electronic device 20 is, but not limited to, a tablet or a notebook computer for illustration purposes only. The electronic device 20 includes a movable module 21 (such as a cover or a display screen) and a device body module 22 with an information input section 29. A support arm 23 is disposed between the movable module 21 and the device body module 22. The support arm 23 is pivotally connected to the movable module 21 and the device body module 22 via rotational shafts 24 respectively. After the movable module 21 is rotated and opened, the support arm 23 serves to support and locate the movable module 21 on the device body module 22 for a user to watch or operate.

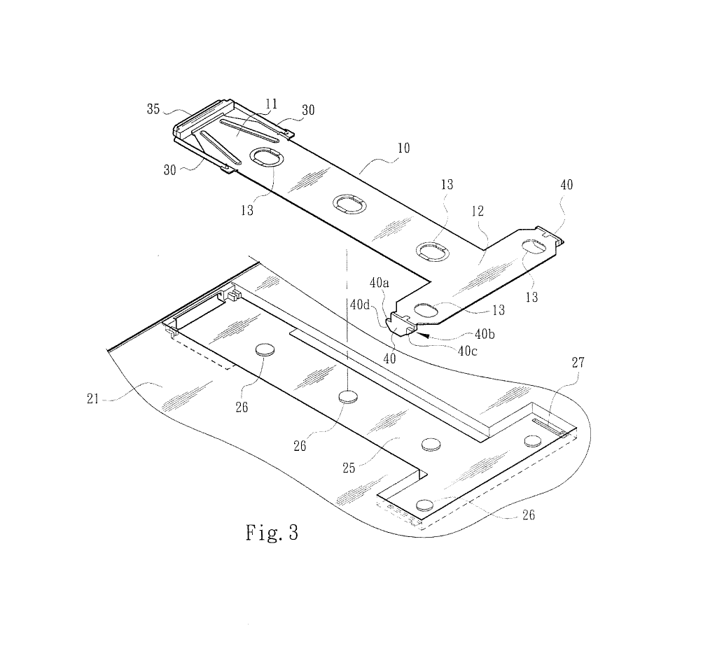

In a preferred embodiment, the connection arm 10 is a T-shaped plate member disposed on the movable module 21. To speak more specifically, the movable module 21 is formed with a cavity 25 for receiving the connection arm 10. The connection arm 10 is movable between a first position and a second position within the cavity 25. As shown in FIG. 3, the connection arm 10 is formed with at least one restriction section 13 in the form of a slot. At least one stop section 26 is disposed in the cavity 25 correspondingly inlaid in the restriction section 13 to together define a move range of the connection arm 10. In other words, the stop section 26 has the form of a pile corresponding to the slot form of the restriction section 13. It should be noted that alternatively, the restriction section 13 can be in the form of a pile, while the stop section 26 can be in the form of a slot.

It should be noted that the first position means a start position of the connection arm 10 or a closed or locked position where the movable module 21 is fully closed onto the device body module 22. The second position means a position where the connection arm 10 is positioned after pushed by an external force or an opened or unlocked position where the movable module 21 can be rotated and opened.

Referring to FIGS. 1, 2 and 3, the connection arm 10 has a first and 11 and a second end 12. An elastic unit 30 is disposed at the first end 11 of the connection arm 10 to normally keep the connection arm 10 positioned in the first position. Substantially, the elastic unit 30 has the form of a coiled spring having two ends. One end of the elastic unit 30 is affixed to the movable module 21 (or the cavity 25), while the other end of the elastic unit 30 is pivotally connected to the connection arm 10. A push section 35 is disposed at the first end 11 of the connection arm 10. The push section 35 protrudes from the movable module 21 for a user to push the connection arm 10 from the first position to the second position.

At least one locking section 40 is disposed at the second end 12 of the connection arm 10. In this embodiment, there are two locking sections 40, which are perpendicularly symmetrically disposed on two sides of the second end 12 respectively. Two slits 27 are formed on the cavity 25. The locking sections 40 protrude through the slits 27 out of the movable module 21 and can be held in dents 28 formed on the device body module 22. In this embodiment, the slits 27 are substantially L-shaped.

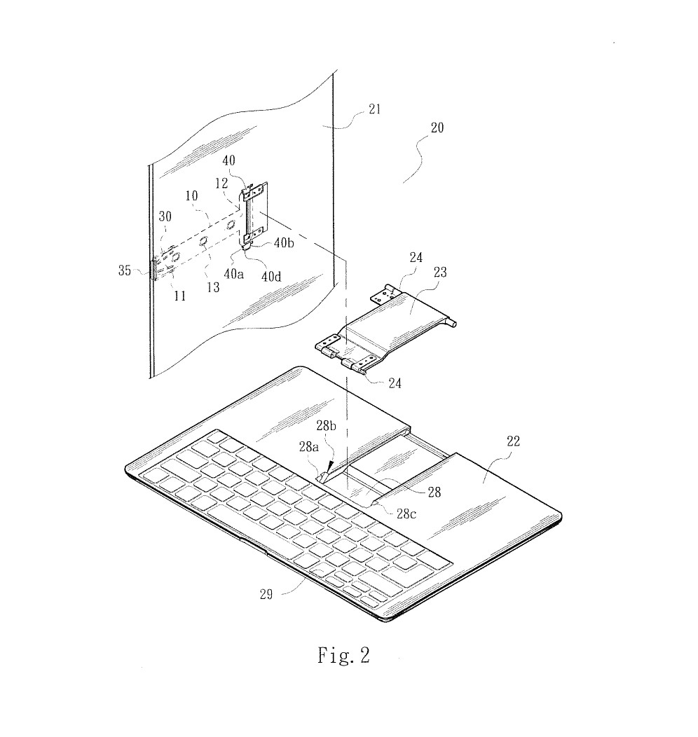

Please now refer to FIGS. 2, 3 and 4. Each locking section 40 has a latch 40a and a guide section 40b. The dent 28 is formed with a stop section 28a and a sidewall 28b corresponding to the latch 40a and the guide section 40b respectively. To speak more specifically, the guide section 40b is in the form of a slope and has a key section 40c. Corresponding to the slope form of the guide section 40b of the locking section 40 and the key section 40c, the sidewall 28b of the dent 28 is also in the form of a slope and has a recess 28c for receiving the key section 40c. Accordingly, when the connection arm 10 is moved between the first and second positions, the guide section 40b of the locking section 40 will move along the sidewall 28b of the dent 28 to make the latch 40a latched with the stop section 28a or unlatched from the stop section 28a. In this case, the movable module 21 can be fully opened or closed onto the device body module 22.

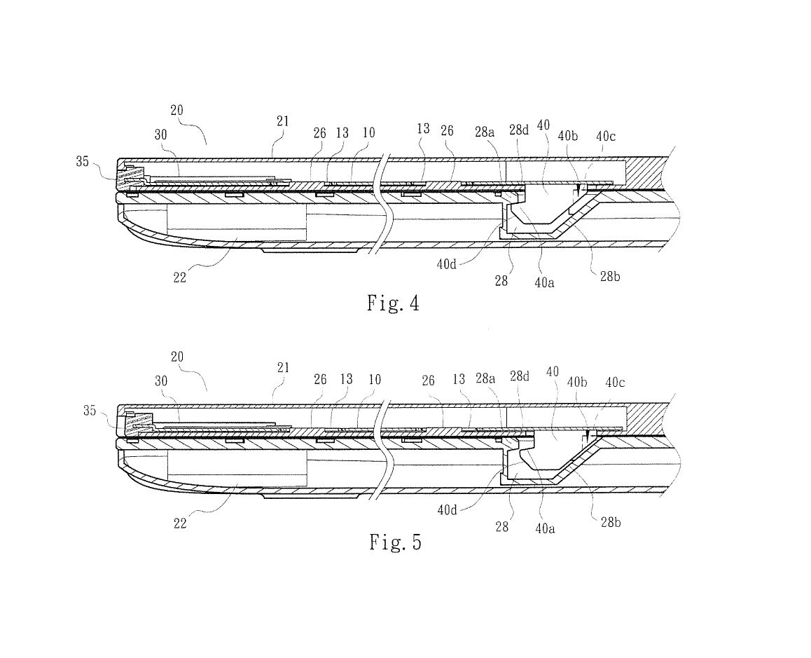

Please now refer to FIGS. 4 and 5. FIG. 4 shows that the connection arm 10 is positioned in the first position with the latch 40a latched with the stop section 28a. Under such circumstance, the movable module 21 is fully closed on the device body module 22 in a locked state. When a user pushes the push section 35 to move the connection arm 10 to the second position, the elastic unit 30 stores energy and the locking section 40 is moved to a right side of FIG. 4. At this time, the latch 40a is moved away from the stop section 28a and unlatched from the stop section 28a into an unlocked state as shown in FIG. 5. Under such circumstance, by means of the support arm 23 and the cooperative rotational shaft 24, the movable module 21 can be rotated and opened and located on the device body module 22 for a user to watch and operate.

It should be noted that when the push force applied to the push section 35 disappears, the elastic unit 30 will release the previously stored energy to make the connection arm 10 move from the second position back to the first position.

When a user attempts to rotate and close the movable module 21 onto the device body module 22, the user can push the push section 35 to make the latch 40a avoid the stop section 28a. After the push section 35 is released, the elastic unit 30 will make the connection arm 10 move back to the first position where the latch 40a is latched with the stop section 28a in a locked state.

In another preferred embodiment, the latch 40a is formed with a slope 40d and/or the stop section 28a is formed with guide side 28d. With the slope 40d and the guide side 28d, a user can directly press the movable module 21 onto the device body module 22 into the locked state without pushing the push section 35.

According to the above arrangement, the electronic device opening/closing control mechanism of the present invention is lightweight, miniaturized and slimmed. In comparison with the conventional mechanism, the present invention has the following advantages:
1. The structures and usage of the movable module 21, the device body module 22 and the relevant components are redesigned and different from those of the conventional device. For example, the connection arm 10 is disposed between the movable module 21 and the device body module 22 and movable between the first and second positions. The elastic unit 30 is connected between the movable module 21 and the connection arm 10. The latch 40a of the locking section 40 can be latched with or unlatched from the stop section 28a of the dent 28 to lock or unlock the movable module 21. In contrast, in the conventional mechanism, due to the slimmed structure and narrow interior space of the electronic device, the locking unit cannot be mounted on one side of the electronic device, which side is proximal to a user. In case that the locking unit is to be mounted on the proximal side, it is necessary to increase the total thickness or volume of the electronic device.
2. By means of the push section 35 of the connection arm 10 and the elastic unit 30, a user can conveniently push the connection arm 10 to unlatch the latch 40a of the locking section 40 from the stop section 28a of the dent 28 or latch the latch 40a with the stop section 28a.

The above embodiments are only used to illustrate the present invention, not intended to limit the scope thereof. Many modifications of the above embodiments can be made without departing from the spirit of the present invention.

What is claimed is:

1. An electronic device opening/closing control mechanism, which is assembled with an electronic device including a movable module and a device body module, the control mechanism comprising:
a connection arm movable between a first position and a second position, the connection arm having a first end and a second end;
an elastic unit disposed at the first end of the connection arm to normally apply an elastic force to the connection arm for keeping the connection arm positioned in the first position; and
a locking section disposed at the second end of the connection arm, the locking section being held in a dent formed on the electronic device, when the connection arm is moved to the second position, the locking section being released from the held state.

2. The electronic device opening/closing control mechanism as claimed in claim 1, wherein the electronic device is formed with a cavity for receiving the connection arm, whereby the connection arm is movable between the first and second positions within the cavity.

3. The electronic device opening/closing control mechanism as claimed in claim 2, wherein the connection arm is formed with at least one restriction section and at least one stop section is disposed in the cavity corresponding to and assembled with the restriction section.

4. The electronic device opening/closing control mechanism as claimed in claim 3, wherein the restriction section is in the form of a slot, while the stop section is in the form of a pile.

5. The electronic device opening/closing control mechanism as claimed in claim 3, wherein the restriction section is in the form of a pile, while the stop section is in the form of a slot.

6. The electronic device opening/closing control mechanism as claimed in claim 1, wherein the elastic unit has the form of a coiled spring.

7. The electronic device opening/closing control mechanism as claimed in claim 1, wherein the elastic unit has two ends, one end of the elastic unit being affixed to the movable module, while the other end of the elastic unit being pivotally connected to the connection arm.

8. The electronic device opening/closing control mechanism as claimed in claim 1, wherein a push section is disposed at the first end of the connection arm.

9. The electronic device opening/closing control mechanism as claimed in claim 8, wherein the push section protrudes from the movable module.

10. The electronic device opening/closing control mechanism as claimed in claim 1, wherein the locking section is perpendicular to the connection arm.

11. The electronic device opening/closing control mechanism as claimed in claim 1, wherein there are two locking sections, which are symmetrically disposed on two sides of the second end respectively.

12. The electronic device opening/closing control mechanism as claimed in claim 2, wherein a slit is formed on the cavity and the locking section protrudes through the slit out of the electronic device.

13. The electronic device opening/closing control mechanism as claimed in claim 12, wherein the slit is L-shaped.

14. The electronic device opening/closing control mechanism as claimed in claim 1, wherein the locking section has a latch and the dent is formed with a stop section corresponding to the latch.

15. The electronic device opening/closing control mechanism as claimed in claim 1, wherein the locking section has a guide section and the dent is formed with a sidewall corresponding to the guide section.

16. The electronic device opening/closing control mechanism as claimed in claim 15, wherein the guide section is in the form of a slope and has a key section and the sidewall of the dent is also in the form of a slope and has a recess for receiving the key section.

17. The electronic device opening/closing control mechanism as claimed in claim 1, wherein the connection arm has the form of a T-shaped plate.

18. The electronic device opening/closing control mechanism as claimed in claim 1, wherein the connection arm is disposed on the movable module and the movable module is formed with a cavity for receiving the connection arm.

19. The electronic device opening/closing control mechanism as claimed in claim 1, wherein the connection arm is disposed on the device body module and the device body module is formed with a cavity for receiving the connection arm.

20. The electronic device opening/closing control mechanism as claimed in claim 1, wherein the dent is formed on the movable module.

21. The electronic device opening/closing control mechanism as claimed in claim 1, wherein the dent is formed on the device body module.

22. The electronic device opening/closing control mechanism as claimed in claim 1, wherein a support arm is disposed between the movable module and the device body module, the support arm being pivotally connected to the movable module and the device body module via rotational shafts respectively.

23. The electronic device opening/closing control mechanism as claimed in claim 14, wherein the latch is formed with a slope.

24. The electronic device opening/closing control mechanism as claimed in claim 14, wherein the stop section is formed with a guide side.
